(19) United States
(12) Patent Application Publication
(10) Pub. No.: US 2021/0218925 A1
(43) Pub. Date: Jul. 15, 2021

(54) IMAGING DEVICE, IMAGING DEVICE CONTROL METHOD, AND ELECTRONIC APPARATUS

(71) Applicant: SONY SEMICONDUCTOR SOLUTIONS CORPORATION, KANAGAWA (JP)

(72) Inventors: NAOTO NAGAKI, KANAGAWA (JP); TAKASHI YOKOKAWA, KANAGAWA (JP); ATSUSHI KITAHARA, KANAGAWA (JP); YUKIYASU TATSUZAWA, KANAGAWA (JP)

(21) Appl. No.: 15/733,887

(22) PCT Filed: Mar. 27, 2019
(86) PCT No.: PCT/JP2019/013323

§ 371 Date: Dec. 1, 2020

(30) Foreign Application Priority Data
Jun. 8, 2018 (JP) 2018-110276

(51) Int. Cl. H04N 5/3745; H04N 5/378; H04N 5/365; H04N 5/369; H01L 27/146

(52) U.S. Cl. CPC H04N 5/37455; H04N 5/378; H01L 27/14643; H04N 5/3698; H01L 27/14612; H04N 5/3658

(57) ABSTRACT

[Problem] To provide an imaging device capable of generating an image with reduced noise. [Solution] Provided is an imaging device including: a signal output unit configured to output a predetermined signal; a switch unit configured to output either an output from the signal output unit or an output from a pixel array configured to output a pixel signal by photoelectric conversion in a switching manner; and a signal processing unit configured to execute signal processing using an output from the switch unit.

### FIELD

The present disclosure relates to an imaging device, an imaging device control method, and an electronic apparatus.

### BACKGROUND

A conventional CMOS image sensor compares an analog pixel signal with a reference signal having a linearly decreasing ramp waveform by a comparator and counts a time required for the reference signal to fall below the pixel signal to AD (analog-to-digital) converts the pixel signal (e.g., refer to Patent Literature 1).

### CITATION LIST

### Patent Literature

Patent Literature 1: JP 2009-124513 A

### SUMMARY

### Technical Problem

Variations in an analog circuit used in the comparator or the like of the CMOS image sensor cause a fixed pattern noise phenomenon. In particular, when a power supply voltage of the comparator is lowered in order to reduce the power consumption of the CMOS image sensor, vertical line noise becomes more likely to occur.

Thus, the present disclosure proposes an imaging device, an imaging device control method, and an electronic apparatus that are new and improved and capable of generating an image with reduced noise.

### Solution to Problem

According to the present disclosure, an imaging device is provided. The imaging device includes a pixel array including a plurality of pixels each configured to output a pixel signal by photoelectric conversion, a signal output unit configured to output a predetermined signal, a switch unit configured to output either an output from the signal output unit or an output based on the pixel signal in a switching manner, and an AD conversion processing unit configured to execute AD conversion using an output from the switch unit.

Moreover, according to the present disclosure, an imaging device control method for controlling an imaging device. The imaging device includes a pixel array including a plurality of pixels each configured to output a pixel signal by photoelectric conversion, a signal output unit configured to output a predetermined signal, a switch unit configured to output either an output from the signal output unit or an output based on the pixel signal in a switching manner, and an AD conversion processing unit configured to execute AD conversion using an output from the switch unit. The method includes performing control for switching the switch unit so as to output the output from the signal output unit to the AD conversion processing unit when a predetermined condition is satisfied.

Moreover, according to the present disclosure, an electronic apparatus includes an imaging device, and a processing unit configured to process a signal output from the imaging device, wherein the imaging device includes a pixel array including a plurality of pixels each configured to output a pixel signal by photoelectric conversion, a signal output unit configured to output a predetermined signal, a switch unit configured to output either an output from the signal output unit or an output based on the pixel signal in a switching manner, and an AD conversion processing unit configured to execute AD conversion using an output from the switch unit.

### Advantageous Effects of Invention

As described above, the present disclosure can provide an imaging device, an imaging device control method, and an electronic apparatus that are new and improved and capable of generating an image with reduced noise.

Note that the effects of the present disclosure are not necessarily limited to the above effect. The present disclosure may achieve, in addition to or instead of the above effect, any effect described in the specification or another effect that can be grasped from the specification.

### BRIEF DESCRIPTION OF DRAWINGS

FIG. 1 is an explanatory diagram illustrating a configuration example of a CMOS image sensor according to an embodiment of the present disclosure.

FIG. 2A is a circuit diagram illustrating a configuration example of a pixel included in a pixel unit.

FIG. 2B is an explanatory diagram illustrating a configuration example of a column readout circuit.

FIG. 3A is a circuit diagram illustrating a configuration example of a comparator of FIG. 1.

FIG. 3B is a diagram illustrating an operation point of the comparator of FIG. 3A.

FIG. 4 is a timing chart describing the operation of the comparator.

FIG. 5 is a circuit diagram illustrating a configuration example of the comparator.

FIG. 6 is an explanatory diagram illustrating a functional configuration example of a signal processing circuit according to the embodiment of the present disclosure.

FIG. 7A is a flowchart illustrating an operation example of the CMOS image sensor according to the embodiment.

FIG. 7B is a flowchart illustrating the operation example of the CMOS image sensor according to the embodiment.

FIG. 8 is an explanatory diagram illustrating an example of correction processing by the signal processing circuit.

FIG. 9 is an explanatory diagram illustrating the operation of the CMOS image sensor according to the embodiment on a time-series basis.

FIG. 10 is an explanatory diagram illustrating image examples of correction processing at startup and every-V correction processing.

FIG. 11 is a circuit diagram illustrating a configuration example of the comparator.

FIG. 12 is a circuit diagram illustrating a configuration example of the comparator.

FIG. 13 is an explanatory diagram illustrating a configuration example of an SAR ADC included in the column readout circuit.

FIG. 14 is an explanatory diagram illustrating a configuration example of the SAR ADC included in the column readout circuit.

FIG. 15 is an explanatory diagram illustrating a configuration example of the CMOS image sensor according to the embodiment.

FIG. 16 is a diagram illustrating an overview of a configuration example of a stacked solid-state imaging apparatus to which the technique according to the present disclosure is applicable.

FIG. 17 is a sectional view illustrating a first configuration example of the stacked solid-state imaging apparatus.

FIG. 18 is a sectional view illustrating a second configuration example of the stacked solid-state imaging apparatus.

FIG. 19 is a sectional view illustrating a third configuration example of the stacked solid-state imaging apparatus.

FIG. 20 is a sectional view illustrating another configuration example of the stacked solid-state imaging apparatus to which the technique according to the present disclosure is applicable.

FIG. 21 is an explanatory diagram illustrating a configuration example of an electronic apparatus.

### DESCRIPTION OF EMBODIMENTS

Hereinbelow, a preferred embodiment of the present disclosure will be described in detail with reference to the accompanying drawings. Note that, in the specification and drawings, elements having substantially the same functional configuration are designated by the same reference sign to omit redundant description.

Note that the description will be made in the following order.

1. Embodiment of the Present Disclosure
1.1 Configuration Example of CMOS Image Sensor
1.2 Operation Example of CMOS Image Sensor

2. Configuration Example of Stacked Solid-state Imaging Apparatus

3. Summary

### 1. Embodiment of the Present Disclosure

[1.1. Configuration Example of CMOS Image Sensor]

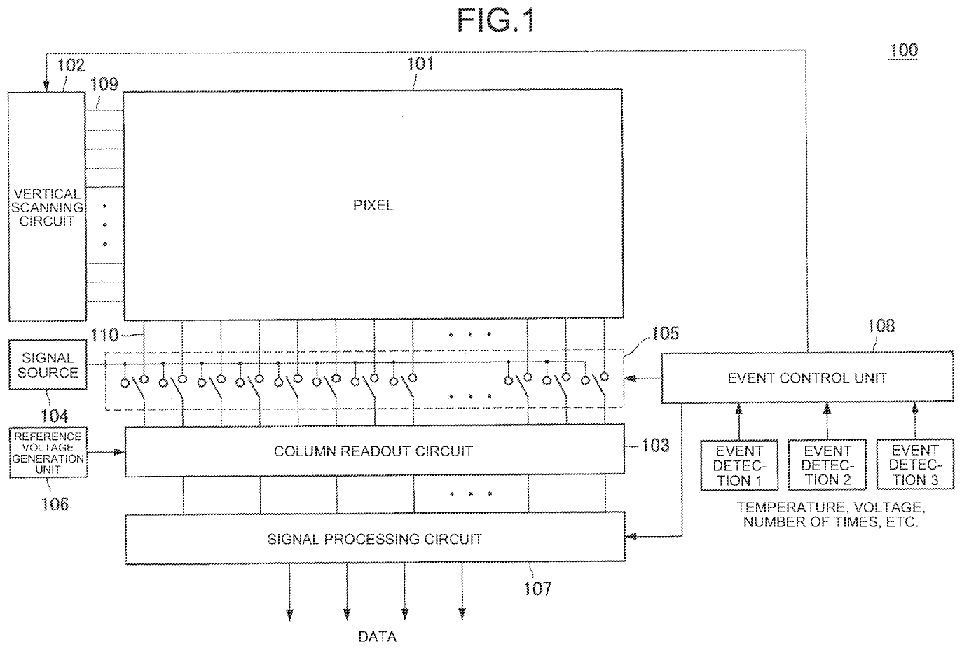

First, a configuration example of a CMOS image sensor according to an embodiment of the present disclosure will be described. FIG. 1 is an explanatory diagram illustrating the configuration example of the CMOS image sensor according to the embodiment of the present disclosure. Hereinbelow, the configuration example of the CMOS image sensor according to the embodiment of the present disclosure will be described with reference to FIG. 1.

As illustrated in FIG. 1, a CMOS image sensor 100 according to the embodiment of the present disclosure includes a pixel unit 101, a vertical scanning circuit 102, a column readout circuit 103, a signal source 104, a switch unit 105, a reference voltage generation unit 106, a signal processing circuit 107, and an event control unit 108.

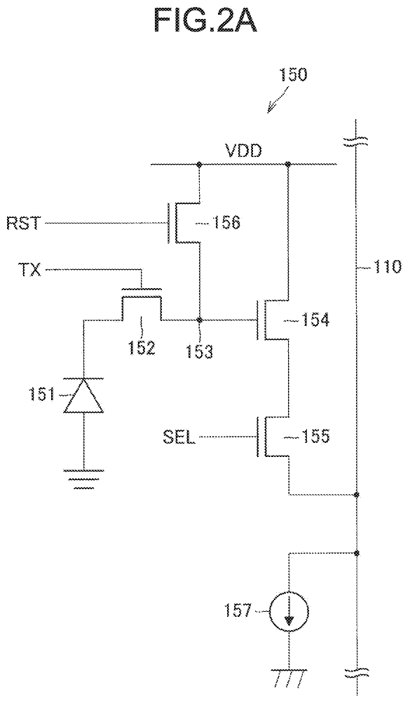

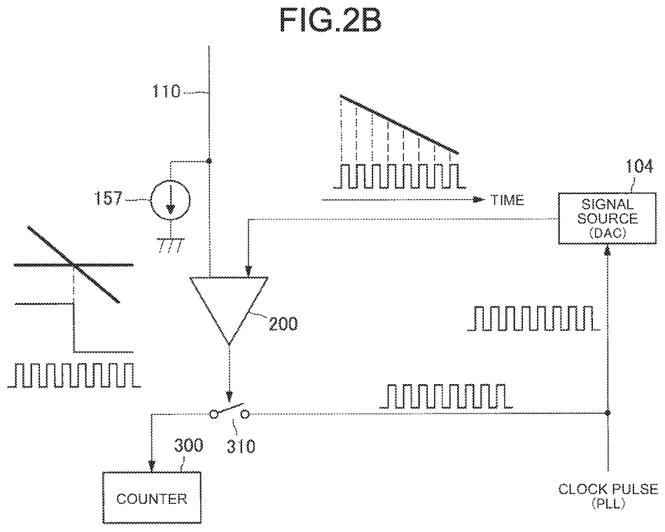

The pixel unit 101 includes unit pixels (hereinbelow, also merely referred to as the pixels) arranged in matrix, each of the unit pixels including a photoelectric conversion element which photoelectrically converts incident light to charge of an amount corresponding to the amount of the incident light. A concrete circuit configuration of the unit pixel will be described below with reference to FIG. 2A. Further, the pixel unit 101 includes pixel driving lines 109 which extend in a right-left direction of the drawing (the pixel array direction in the pixel row/the horizontal direction) for the respective rows, and vertical signal lines 110 which extend in an up-down direction of the drawing (the pixel array direction in the pixel column/the vertical direction) for the respective columns on the pixel array in matrix. One end of each of the pixel driving lines 109 is connected to an output end of the vertical scanning circuit 102, the output end corresponding to each row. Note that although one pixel driving line 109 is illustrated for each pixel row, two or more pixel driving lines 109 may be provided for each pixel row.

The vertical scanning circuit 102 includes a shift resister and an address recorder. Although the concrete configuration is not illustrated in the present embodiment, the vertical scanning circuit 102 includes a readout scanning system and a sweep-out scanning system.

The readout scanning system performs selective scanning in order on unit pixels from which signals are to be read out in units of rows. On the other hand, the sweep-out scanning system performs sweep-out scanning on the readout row on which readout scanning is performed by the readout scanning system to sweep out (reset) unnecessary charge from the photoelectric conversion elements of the unit pixels in the readout row in prior to the readout scanning by a time of a shutter speed. A so-called electronic shutter operation is performed by the sweep-out (reset) of unnecessary charge by the sweep-out scanning system. Here, the electronic shutter operation refers to an operation of discharging optical charge of the photoelectric conversion element and starting new light exposure (starting accumulation of optical charge). A signal read out by the readout operation by the readout scanning system corresponds to the amount of incident light after the immediately preceding readout operation or the immediately preceding electronic shutter operation. Further, a period from a readout timing of the immediately preceding readout operation or a sweep-out timing of the immediately preceding electron shutter operation to a readout timing of the current readout operation corresponds to an accumulation time of optical charge (light exposure time) in the unit pixels.

A pixel signal VSL which is output from each unit pixel in the pixel row selectively scanned by the vertical scanning circuit 102 is fed to the column readout circuit 103 through the vertical signal line 110 in each corresponding column.

The column readout circuit 103 includes a comparator, a counter, and a latch. One comparator, one counter, and one latch are provided per column or per a plurality of columns of the pixel unit 101 to constitute an ADC. That is, in the column readout circuit 103, one ADC is provided per column or per a plurality of columns of the pixel unit 101. A concrete configuration example of the comparator will be described below. Further, a predetermined reference voltage is applied to the comparator of the column readout circuit 103. A configuration example of the column readout circuit 103 will be described with reference to FIG. 2B.

The signal source 104 is an example of the signal output unit of the present disclosure, and feeds a signal to the column readout circuit 103 through the switch unit 105. The signal from the signal source 104 is fed to the column readout circuit 103 when the CMOS image sensor 100 executes processing for correcting a characteristic of the column readout circuit 103 (hereinbelow, also merely referred to as the correction processing). The signal source 104 may be configured to output a signal of any voltage, and may include a plurality of signal sources each of which outputs a signal of a predetermined voltage.

The switch unit 105 executes a switching operation of feeding either the signal from the pixel unit 101 or the signal from the signal source 104 to the column readout circuit 103. More specifically, the switch unit 105 establishes connection to supply the signal from the pixel unit 101 to the column readout circuit 103 in imaging and establishes connection to supply the signal from the signal source 104 to the column readout circuit 103 in correction processing. Switching of the switch unit 105 may be controlled by the event control unit 108. The switch unit 105 includes switching elements provided for the respective vertical signal lines 110. Switching of each of the switching elements is controlled by the event control unit 108.

The signal processing circuit 107 performs predetermined signal processing on a digital pixel signal to generate two-dimensional image data. For example, the signal processing circuit 107 performs correction of a vertical line defect or a point defect, or clamping of a signal, and performs digital signal processing such as parallel-serial conversion, compression, coding, summing, averaging, and intermittent operation. The signal processing circuit 107 outputs the generated image data to a device in the subsequent stage.

In the present embodiment, the signal processing circuit 107 executes correction processing for correcting the analog characteristic of the column readout circuit 103. The signal processing circuit 107 can reduce noise caused by the analog characteristic of the column readout circuit 103 by executing the correction processing.

The event control unit 108 detects the occurrence of a predetermined event, and controls operations of the vertical scanning circuit 102, the switch unit 105, and the signal processing circuit 107 according to the detection. Thus, the event control unit 108 is an example of the control unit of the present disclosure. For example, in a case where it is predetermined that the correction processing is executed upon detection of a predetermined temperature change, when the predetermined temperature change is detected by a temperature sensor (not illustrated), the event control unit 108 switches the switch unit 105 so as to connect the signal source 104 to the column readout circuit 103 in order to execute the correction processing. Further, for example, in a case where it is predetermined that the correction processing is executed upon detection of a predetermined voltage change inside the CMOS image sensor 100, when the predetermined voltage change is detected, the event control unit 108 switches the switch unit 105 so as to connect the signal source 104 to the column readout circuit 103 in order to execute the correction processing.

Driving of the vertical scanning circuit 102, the column readout circuit 103, the signal source 104, the switch unit 105, the reference voltage generation unit 106, and the signal processing circuit 107 may be controlled in accordance with a timing signal from a timing control circuit (not illustrated).

### Configuration Example of Pixel

FIG. 2A is a circuit diagram illustrating a configuration example of a pixel 150 included in the pixel unit 101.

The pixel 150 includes, for example, a photodiode 151 as the photoelectric conversion element, and includes four transistors: a transfer transistor 152; an amplification transistor 154; a selection transistor 155; and a reset transistor 156 as active elements for the photodiode 151.

The photodiode 151 photoelectrically converts incident light to charge (electrons in the present embodiment) of an amount corresponding to the amount of the incident light.

The transfer transistor 152 is connected between the photodiode 151 and a floating diffusion (FD) 153. The transfer transistor 152 transfers charge accumulated on the photodiode 151 to the FD 153 when turned on by a driving signal TX which is fed from the vertical scanning circuit 102.

A gate of the amplification transistor 154 is connected to the FD 153. The amplification transistor 154 is connected to the vertical signal line 110 through the selection transistor 155 to constitute a source follower with a constant current source 157 outside the pixel unit 101. When the selection transistor 155 is turned on by a driving signal SEL which is fed from the vertical scanning circuit 102, the amplification transistor 154 amplifies the potential of the FD 153 and outputs a pixel signal indicating a voltage corresponding to the amplified potential to the vertical signal line 110. Then, the pixel signal output from each pixel 150 is fed to each comparator of the column readout circuit 103 through the vertical signal line 110.

The reset transistor 156 is connected between a power supply VDD and the FD 153. When the reset transistor 156 is turned on by a driving signal RST which is fed from the vertical scanning circuit 102, the potential of the FD 153 is reset to the potential of the power supply VDD.

### Configuration Example of Column Readout Circuit

FIG. 2B is an explanatory diagram illustrating a configuration example of the column readout circuit 103. The column readout circuit 103 includes a comparator 200, a counter 300, and a switch 310.

The comparator 200 is a circuit that compares an output signal from the vertical signal line 110 with a ramp signal from the signal source 104. The ramp signal from the signal source 104 has a waveform having a value changing with time with a constant slope in accordance with a clock pulse from a PLL (not illustrated). The comparator 200 outputs a signal for turning off the switch 310 at a reversal timing of the high/low relationship between the output signal from the vertical signal line 110 and the ramp signal from the signal source 104.

The counter 300 is a circuit that counts up in accordance with the clock pulse from the PLL. The counter 300 counts up until the switch 310 is turned off to stop the supply of the clock pulse from the PLL. In other words, the counter 300 counts up until the reversal timing of the high/low relationship between the output signal from the vertical signal line 110 and the ramp signal from the signal source 104. Thus, a value of the counter 300 corresponds to a digital value of the output signal from the vertical signal line 110.

### Configuration Example of Comparator

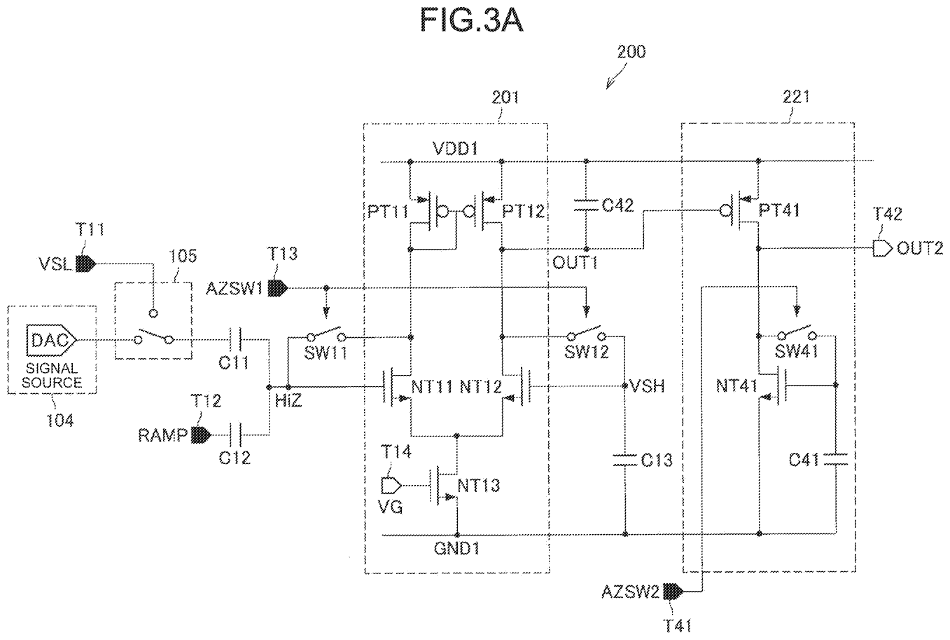

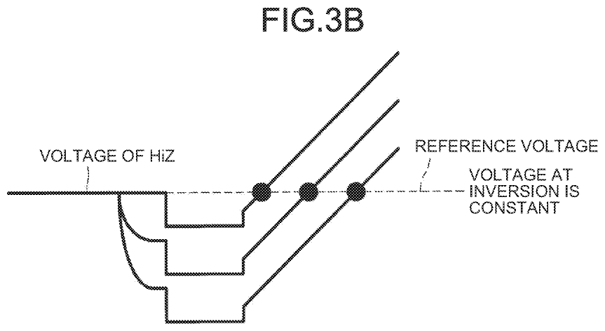

FIG. 3A is a circuit diagram illustrating a configuration example of the comparator 200 which is applied to a comparator 121 of FIG. 1.

The comparator 200 includes a differential amplifier 201, an output amplifier 221, capacitors C11 to C13, C42, a switch SW11, and a switch SW12. The differential amplifier 201 includes a PMOS transistor PT11, a PMOS transistor PT12, and NMOS transistors NT11 to NT13.

A source of the PMOS transistor PT11 and a source of the PMOS transistor PT12 are connected to a power supply VDD1. A drain of the PMOS transistor PT11 is connected to a gate of the PMOS transistor PT11 and a drain of the NMOS transistor NT11. A drain of the PMOS transistor PT12 is connected to a drain of the NMOS transistor NT12 and an output terminal T15 of an output signal OUT1. A source of the NMOS transistor NT11 is connected to a source of the NMOS transistor NT12 and a drain of the NMOS transistor NT13. A source of the NMOS transistor NT13 is connected to a ground GND1.

The PMOS transistor PT11 and the PMOS transistor PT12 constitute a current mirror circuit. Further, the NMOS transistors NT11 to NT13 constitute a differential comparison unit. More specifically, the NMOS transistor NT13 operates as a current source by a bias voltage VG which is input from the outside through an input terminal T14, and the NMOS transistor NT11 and the NMOS transistor NT112 operate as a differential transistor.

The capacitor C11 is connected between an input terminal T11 of the pixel signal VSL or the signal source 104 which is capable of outputting any voltage and a gate of the NMOS transistor NT11, and serves as an input capacitor for the pixel signal VSL.

The capacitor C12 is connected between an input terminal T12 of a reference signal RAMP and a gate of the NMOS transistor NT11, and serves as an input capacitor for the reference signal RAMP.

The switch SW11 is connected between the drain and the gate of the NMOS transistor NT11, and turned on or off in accordance with a driving signal AZSW1 which is input through an input terminal T13.

The switch SW12 is connected between the drain and a gate of the NMOS transistor NT12, and turned on or off in accordance with the driving signal AZSW1 which is input through the input terminal T13.

The capacitor C13 is connected between the gate of the NMOS transistor NT12 and the ground GND1.

Note that, hereinbelow, a connection point between the capacitor C11, the capacitor C12, and the switch SW11 is referred to as a node HiZ. Further, hereinbelow, a connection point between the gate of the NMOS transistor NT12, the capacitor C13, and the switch SW12 is referred to as a node VSH.

The output amplifier 221 functions as a buffer that buffers the output signal OUT1 of the differential amplifier 201 to output the output signal OUT1 at an appropriate level to a circuit in the subsequent stage. More specifically, the output amplifier 221 amplifies the output signal OUT1 of the differential amplifier 201 with a predetermined gain, and outputs an output signal OUT2 obtained as a result thereof from an output terminal T42.

The output amplifier 221 includes a PMOS transistor PT41, an NMOS transistor NT41, a capacitor C41, and a switch SW41.

A source of the PMOS transistor PT41 is connected to the power supply VDD1, a gate thereof is connected to an output of the differential amplifier 201, and a drain thereof is connected to the drain of the PMOS transistor PT41 and the output terminal T42. A source of the NMOS transistor NT41 is connected to the ground GND 1, and a gate thereof is connected to the ground GND 1 through the capacitor C41. The switch SW41 is connected between a drain and the gate of the NMOS transistor NT41, and turned on or off in accordance with a driving signal AZSW2 which is input from the timing control circuit through an input terminal T41.

The capacitor C42 is connected between the power supply VDD1 and the drain of the PMOS transistor PT12 (the output of the differential amplifier 201). The capacitor C42 removes a high-frequency component of the output signal OUT1 of the differential amplifier 201.

### Operation of Comparator

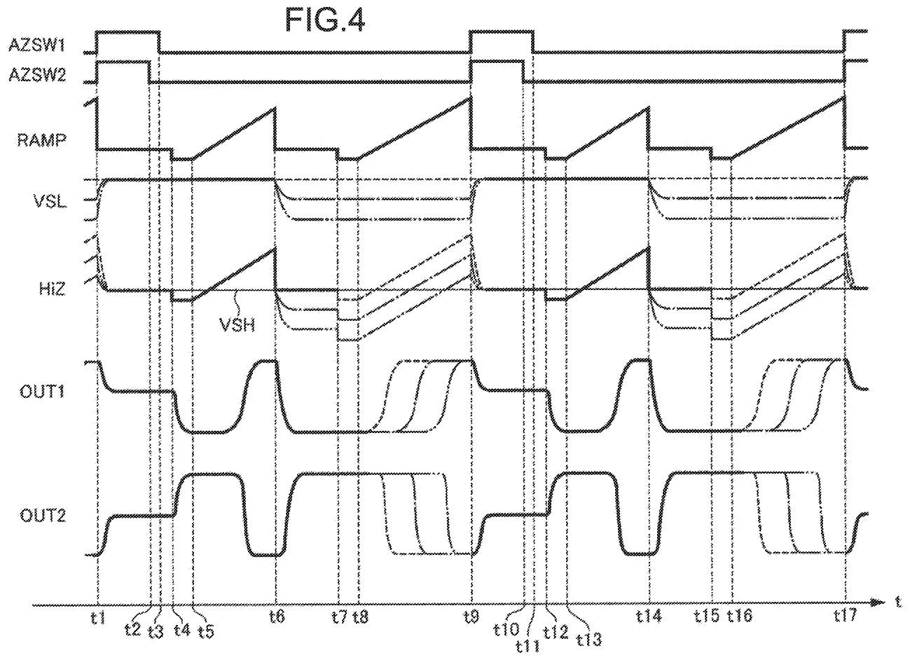

Next, the operation of the comparator 200 will be described with reference to the timing chart of FIG. 4. FIG. 4 illustrates the timing chart of the driving signal AZSW1, the driving signal AZSW2, the reference signal RAMP, the pixel signal VSL, the node VSH, the node HiZ, the output signal OUT1, and the output signal OUT2.

At a time t1, the driving signal AZSW1 is set to a high level. Further, the switch SW11 and the switch SW12 are turned on, so that the drain and the gate of the NMOS transistor NT11 are connected and the drain and the gate of the NMOS transistor NT12 are connected. Further, the reference signal RAMP is set to a predetermined reset level. Further, the FD 153 of the pixel 150 to be a readout target is reset, and the pixel signal VSL is set to a reset level.

Accordingly, an auto-zero operation of the differential amplifier 201 is started. That is, the drain and the gate of the NMOS transistor NT11 and the drain and the gate of the NMOS transistor NT12 converge to a predetermined same voltage (hereinbelow, referred to as a reference voltage). Accordingly, a voltage of the node HiZ and a voltage of the node VSH are set to the reference voltage.

Further, the driving signal AZSW2 is set to a high level. Further, the switch SW41 is turned on, so that the drain and the gate of the PMOS transistor PT41 are connected.

Accordingly, an auto-zero operation of the output amplifier 221 is started. That is, a voltage of the capacitor C41 becomes equal to a drain voltage of the PMOS transistor PT41, and charge is accumulated on the capacitor C41.

At a time t2, the driving signal AZSW2 is set to a low level. Further, the switch SW41 is turned off, so that the auto-zero operation of the output amplifier 221 is finished. Note that, also after the switch SW41 is turned off, the voltage of the capacitor C41 is maintained and applied to the gate of the NMOS transistor NT41. Thus, the NMOS transistor NT41 functions as a current source that passes a current substantially equal to a current passed when the switch SW41 is on.

Next, at a time t3, the driving signal AZSW1 is set to a low level, and the switch SW11 and the switch SW12 are turned off. Accordingly, the auto-zero operation of the differential amplifier 201 is finished. Since the pixel signal VSL and the reference signal RAMP remain unchanged, the voltage of the node HiZ is maintained at the reference voltage. Further, the voltage of the node VSH is maintained at the reference voltage by charge accumulated on the capacitor C13.

At a time t4, the voltage of the reference signal RAMP is lowered by a predetermined value from the reset level. Accordingly, the voltage of the node HiZ drops and falls below the voltage of the node VSH (reference voltage), and the output signal OUT1 of the differential amplifier 201 becomes a low level.

At a time t5, the reference signal RAMP starts linearly increasing. Along with this, the voltage of the node HiZ also linearly increases. Further, a counter 122 starts counting.

Then, when the voltage of the node HiZ exceeds the voltage of the node VSH (reference voltage), the output signal OUT1 of the differential amplifier 201 is inverted to a high level. Further, a count value of the counter 122 at the point when the output signal OUT1 is inverted to a high level is held by a latch 123 as a value of the pixel signal VSL of P phase (reset level).

At a time t6, the voltage of the reference signal RAMP is set to a reset voltage. Further, the transfer transistor 152 of the pixel 150 is turned on, so that charge accumulated on the photodiode 151 during a light exposure period is transferred to the FD 153, and the pixel signal VSL is set to a signal level. Accordingly, the voltage of the node HiZ drops by a value corresponding to the signal level and falls below the voltage of the node VSH (reference voltage), and the output signal OUT1 of the differential amplifier 201 is inverted to a low level.

At a time t7, the voltage of the reference signal RAMP is lowered by a predetermined value from the reset level similarly at the time t4. Accordingly, the voltage of the node HiZ further drops.

At a time t8, the reference signal RAMP starts linearly increasing similarly at the time t5. Along with this, the voltage of the node HiZ also linearly increases. Further, the counter 122 starts counting.

Then, when the voltage of the node HiZ exceeds the voltage of the node VSH (reference voltage), the output signal OUT1 of the differential amplifier 201 is inverted to a high level. Further, a count value of the counter 122 at the point when the output signal OUT1 is inverted to a high level is held by the latch 123 as a value of the pixel signal VSL of D phase (signal level). Further, the latch 123 takes the difference between the D-phase pixel signal VSL and the P-phase pixel signal VSL read out between the time t5 and the time t6 to perform CDS. In this manner, AD conversion of the pixel signal VSL is performed.

Further, when the output signal OUT1 of the differential amplifier 201 becomes a high level, the PMOS transistor PT41 of the output amplifier 221 is turned off, and the output signal OUT2 becomes a low level. On the other hand, when the output signal OUT1 of the differential amplifier 201 becomes a low level, the PMOS transistor PT41 of the output amplifier 221 is turned on, and the output signal OUT2 becomes a high level. That is, the output amplifier 221 outputs the output signal OUT2 at an inverted level of the output signal OUT1 of the differential amplifier 201.

Then, after a time t9, the same operation as performed from the time t1 to the time t8 is repeated.

Accordingly, it is possible to reduce the power consumption of the column readout circuit 103 by lowering the voltage of the power supply VDD1, thereby reducing the power consumption of the CMOS image sensor 100.

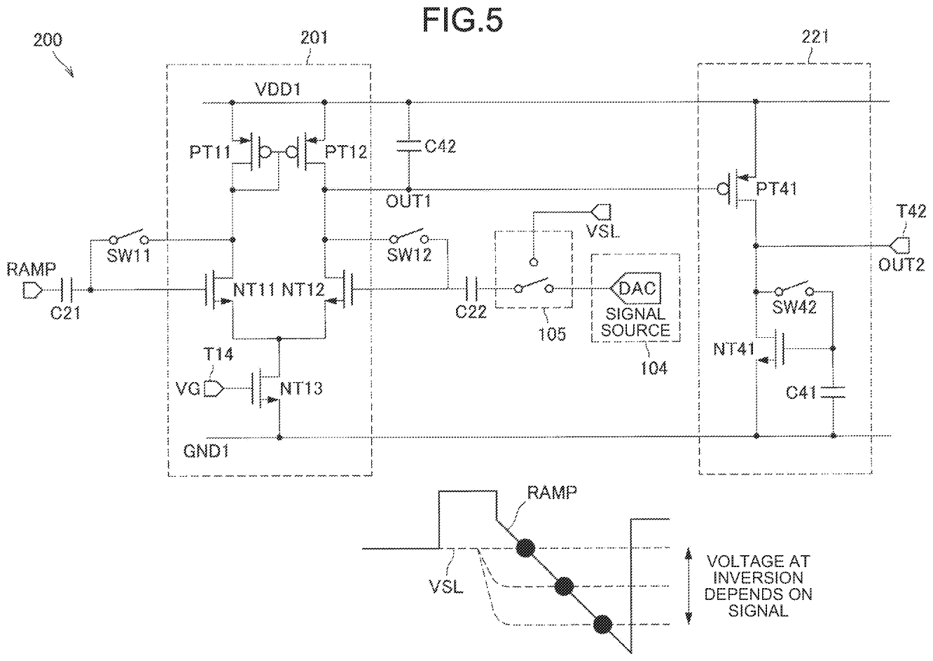

The upper figure of FIG. 5 illustrates a configuration example of the comparator.

In the comparator of FIG. 5, the reference signal RAMP having a linearly decreasing ramp waveform is input to one input of the differential amplifier 201 (the gate of the NMOS transistor NT11) through the capacitor C21. The pixel signal VSL is input to the other input of the differential amplifier 201 (the gate of the NMOS transistor NT12) through the capacitor C22.

Further, as illustrated in the lower figure of FIG. 5, the reference signal RAMP is compared with the pixel signal VSL, and a result of the comparison is output as the output signal OUT. At this time, an input voltage of the differential amplifier 201 (the voltage of the reference signal RAMP and the voltage of the pixel signal VSL) at inversion of the output signal OUT varies according to the voltage of the pixel signal VSL. Thus, for example, when the voltage of the power supply VDD for driving the comparator is lowered, the input voltage of the differential amplifier 201 at inversion of the output signal OUT may exceed an input dynamic range of the comparator, which may make it impossible to obtain sufficient linearity of AD conversion.

On the other hand, in the comparator 200, as described above, a result of the comparison between the voltage of the signal obtained by adding the pixel signal VSL and the reference signal RAMP through the input capacitors (the voltage of the node HiZ) and the voltage of the node VSH (reference voltage) is output as the output signal OUT1. FIG. 3B is an explanatory diagram illustrating an effect of the circuit illustrated in FIG. 3A. In the comparator 200 illustrated in FIG. 3A, the input voltage of the differential amplifier 201 (the voltage of the node HiZ and the voltage of the node VSH) at inversion of the output signal OUT1 does not vary, but remains constant as illustrated in FIG. 3B.

Further, in the CMOS image sensor 100, the reference signal RAMP changes in the direction opposite to the reference signal RAMP of the comparator of FIG. 5, and linearly changes in the direction opposite to the pixel signal VSL. Here, changing in the direction opposite to the pixel signal VSL indicates changing in the direction opposite to the direction in which the pixel signal VSL changes as the signal component becomes larger. For example, in this example, the pixel signal VSL changes in the negative direction as the signal component becomes larger, and, on the other hand, the reference signal RAMP changes in the positive direction opposite thereto. Thus, the voltage of the node HiZ (the input voltage of the differential amplifier 201) is a voltage corresponding to the difference between the pixel signal VSL and the reference signal RAMP of FIG. 5, and the amplitude thereof is small.

Since the input voltage of the differential amplifier 201 at inversion of the output signal OUT1 is constant, and the amplitude of the input voltage is small in this manner, it is possible to narrow the input dynamic range of the differential amplifier 201.

Thus, it is possible to reduce the voltage of the power supply VDD1 for driving the comparator 200 lower than that of the comparator of FIG. 5. As a result, it is possible to reduce the power consumption of the column readout circuit 103, thereby reducing the power consumption of the CMOS image sensor 100.

On the other hand, variations in an analog circuit used in a comparator or the like of a CMOS image sensor cause a fixed pattern noise phenomenon. In particular, when a power supply voltage of the comparator is reduced in order to reduce the power consumption of the CMOS image sensor, vertical line noise becomes more likely to occur.

Thus, the CMOS image sensor 100 according to the present embodiment executes correction processing for correcting the analog characteristic of the column readout circuit 103 by the signal processing circuit 107. The CMOS image sensor 100 according to the present embodiment is capable of generating an image with reduced noise caused by the analog characteristic of the column readout circuit 103 by executing the correction processing by the signal processing circuit 107.

Specifically, in the correction processing, the switch unit 105 is switched to feed the signal from the signal source 104 to each comparator 200. In the case where the signal source 104 is a DAC as illustrated in FIG. 3A, a signal set at any voltage is fed to each comparator 200. Similarly, also in the comparator illustrated in FIG. 5, in the correction processing, the switch unit 105 is switched to feed the signal from the signal source 104 to each comparator. Operating the switch unit 105 in this manner enables the CMOS image sensor 100 according to the present embodiment to correct the analog characteristic of the column readout circuit 103.

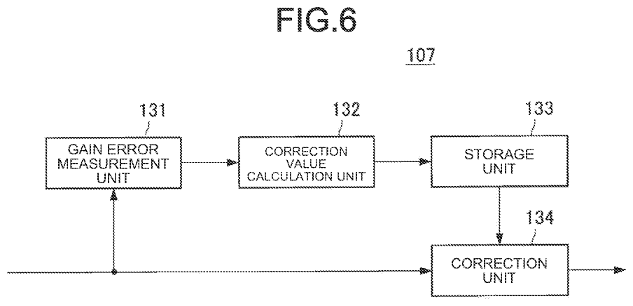

FIG. 6 is an explanatory diagram illustrating a functional configuration example of the signal processing circuit 107 according to the embodiment of the present disclosure. Hereinbelow, the functional configuration example of the signal processing circuit 107 according to the embodiment of the present disclosure will be described with reference to FIG. 6.

As illustrated in FIG. 6, the signal processing circuit 107 according to the embodiment of the present disclosure includes a gain error measurement unit 131, a correction value calculation unit 132, a storage unit 133, and a correction unit 134.

In the correction processing, the gain error measurement unit 131 measures an error of a gain on an output of each ADC included in the column readout circuit 103. An offset and the gain differ between the outputs of the respective ADCs due to variations in the characteristic of the analog circuit. Thus, the gain error measurement unit 131 measures variations in the offset and gain which differ between the outputs of the respective ADCs. That is, the gain error measurement unit 131 measures variations in the offset and gain when the signal from the signal source 104 is converted to a digital signal through the column readout circuit 103.

The correction value calculation unit 132 calculates, on the basis of the error of the gain measured by the gain error measurement unit 131, a correction value for correcting the error of the gain. A concrete correction value calculation example will be described below. The storage unit 133 stores the correction value calculated by the correction value calculation unit 132. The correction unit 134 corrects a signal output from the column readout circuit 103 using the correction value stored in the storage unit 133 in imaging.

The signal processing circuit 107 having such a configuration can reduce noise caused by the analog characteristic of the column readout circuit 103. Thus, the CMOS image sensor 100 according to the embodiment of the present disclosure can generate an image with reduced noise caused by the analog characteristic of the column readout circuit 103 by executing the correction processing by the signal processing circuit 107.

The CMOS image sensor 100 according to the embodiment of the present disclosure can execute the correction processing by the signal processing circuit 107 in response to detection of the occurrence of a predetermined event. Thus, the signal processing circuit 107 may hold information about operating environments of the CMOS image sensor 100, such as a voltage value and a temperature value, at the point when the correction processing is executed.

[1.2. Operation Example of CMOS Image Sensor]

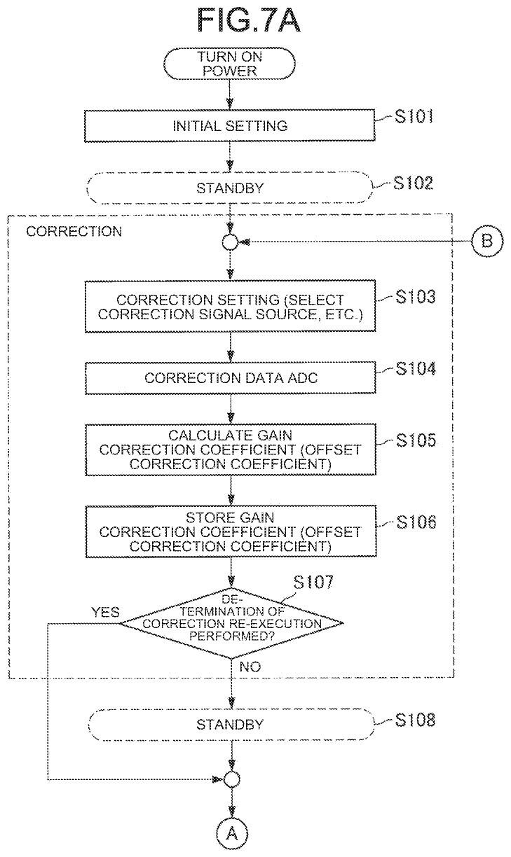

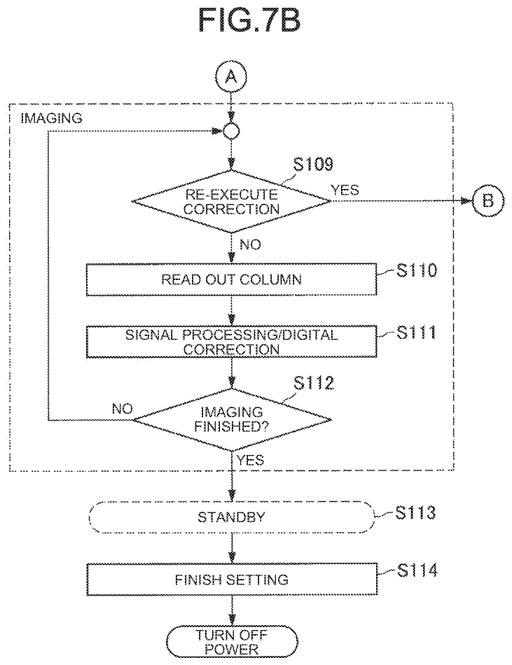

Next, an operation example of the CMOS image sensor 100 according to the embodiment of the present disclosure will be described. FIGS. 7A and 7B are flowcharts illustrating the operation example of the CMOS image sensor 100 according to the embodiment of the present disclosure.

When power is turned on, the CMOS image sensor 100 executes predetermined initial setting (Step S101), and goes on standby (Step S102). When executing correction processing, the CMOS image sensor 100 first executes correction setting (Step S103). The correction setting may be, for example, setting of the voltage of the signal output from the signal source 104 or selection of a signal source to be used in a case where the signal source 104 includes a plurality of signal sources.

After executing the correction setting, the CMOS image sensor 100 executes AD conversion of correction data output from the signal source 104 by the column readout circuit 103 (Step S104). Then, the CMOS image sensor 100 executes calculation of a gain correction coefficient by the correction value calculation unit 132 using the digital signal output from the column readout circuit 103 (Step S105). In step S105, the correction value calculation unit 132 may calculate an offset correction coefficient for offset correction. Then, the CMOS image sensor 100 stores the calculated correction coefficient in the storage unit 133 (Step S106). After storing the correction coefficient in the storage unit 133, the CMOS image sensor 100 determines whether determination of correction re-execution in imaging (described below) has been performed (Step S107). When the determination of the correction re-execution has not been performed (Step S107, No), the CMOS image sensor 100 goes on standby (Step S108). In this standby state, the switch unit 105 performs switching so as to output the output from the pixel unit 101 to the column readout circuit 103. On the other hand, when the determination of the correction re-execution has been performed (Step S107, Yes), the CMOS image sensor 100 does not go on standby, but proceeds to the next process.

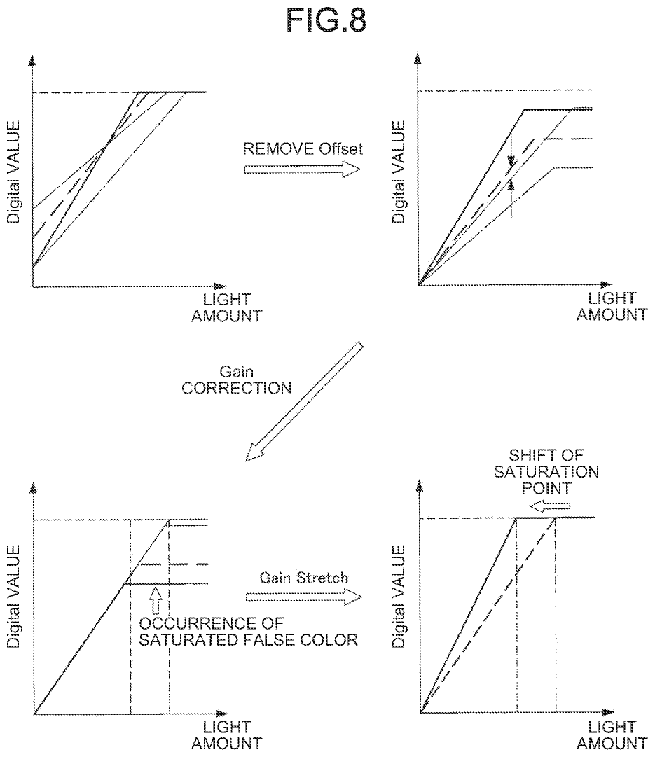

Here, an example of the correction processing by the signal processing circuit 107 will be described. FIG. 8 is an explanatory diagram illustrating an example of the correction processing by the signal processing circuit 107. FIG. 8 illustrates the correction processing by the signal processing circuit 107 when outputs of four ADCs are corrected.

As illustrated in the upper left graph of FIG. 8, a change of the digital value with respect to the light amount is not uniform between all the ADCs due to variations in the characteristic of the analog circuit. The fact that the change of the digital value with respect to the light amount is not uniform between all the ADCs causes vertical line noise.

Thus, the signal processing circuit 107 performs correction processing to make the change of the digital value with respect to the light amount uniform between all the ADCs. For example, as illustrated in the upper right graph of FIG. 8, the signal processing circuit 107 first makes outputs of all the ADCs have the same digital value when the light amount is zero (the same offset value). Then, as illustrated in the lower left graph of FIG. 8, the signal processing circuit 107 performs gain correction on the outputs of all the ADCs, that is, processing for making the outputs of all the ADCs have the same slope. The slope at this time may be the slope of the output of a specific one of the ADCs, or may be an average value of the slopes of the outputs of all the ADCs.

The characteristics of all the ADCs, that is, changes of the digital value with respect to the light amount are made coincide with each other by the gain correction. On the other hand, however, saturation points, that is, light amount values at which the digital values stop increasing do not coincide with each other. In this state, so-called saturated false color occurs. Thus, as illustrated in the lower right graph of FIG. 8, the signal processing circuit 107 executes processing for making the saturation points coincide with each other on the outputs of all the ADCs. The signal processing circuit 107 can make the characteristics of all the ADCs coincide with each other by the above series of processes.

Note that the method described above is merely an example of the operation of the signal processing circuit 107. The signal processing circuit 107 may perform various processing for making the characteristics of the respective ADCs illustrated in the leftmost graph of FIG. 8 coincide with each other as illustrated in the rightmost graph of FIG. 8. Further, although the graphs of FIG. 8 illustrate the relationship between the light amount and the digital value, the present disclosure is not limited to this example. For example, the signal processing circuit 107 may perform processing for making the characteristics of the respective ADCs coincide with each other on the basis of the relationship between a voltage value of a signal generated in the pixel unit 101 based on the light amount and the digital value.

The CMOS image sensor 100 first determines whether the correction processing should be re-executed in imaging (Step S109). A criterion to determine whether the correction processing should be re-executed may be, for example, that the voltage value has changed by a predetermined value or more, that the temperature has changed by a predetermined value or more, that a predetermined time has passed after the preceding correction processing, or that a signal instructing correction has been fed from the outside.

When it is determined that the correction processing should be re-executed (Step S109, Yes), the CMOS image sensor 100 returns to the correction setting processing of Step S103 described above to re-execute the correction processing. The CMOS image sensor 100 can return to the imaging without going through standby in the re-execution of the correction processing in the imaging. On the other hand, when it is determined that the correction processing should not be re-executed (Step S109, No), the CMOS image sensor 100 reads out an output from the pixel unit 101 by the column readout circuit 103 (Step S110), and performs signal processing on the readout data and executes digital correction processing using the coefficient obtained by the correction processing by the signal processing circuit 107 (Step S111).

The CMOS image sensor 100 then determines whether the imaging processing has been finished (Step S112). When the imaging processing has not been finished (Step S112, No), the CMOS image sensor 100 returns to the determination whether the correction processing should be re-executed in Step S109. On the other hand, when the imaging processing has been finished (Step S112, Yes), the CMOS image sensor 100 shifts to the standby mode again (Step S113). Further, when the operation should be finished, the CMOS image sensor 100 executes predetermined finish setting (Step S114), and turns off power.

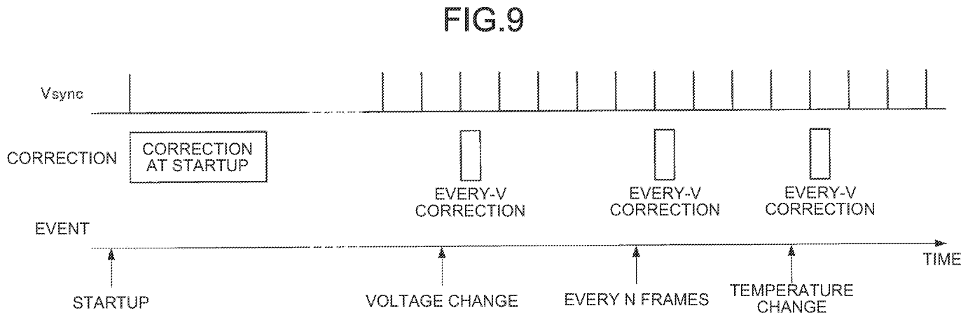

Next, an execution example of the correction processing by the CMOS image sensor 100 based on the occurrence of an event will be described. FIG. 9 is an explanatory diagram illustrating the operation of the CMOS image sensor 100 according to the embodiment of the present disclosure on a time-series basis. When the CMOS image sensor 100 is started as an event, the CMOS image sensor 100 executes correction processing at startup at an output timing of a vertical synchronization signal Vsync. The correction processing at startup may be performed for a longer time than correction processing after startup (described below).

For example, when the voltage inside the CMOS image sensor 100 has changed by a predetermined value or more after the startup of the CMOS image sensor 100, the CMOS image sensor 100 executes correction processing corresponding to the voltage change at the output timing of the vertical synchronization signal Vsync. Further, for example, when the temperature inside the CMOS image sensor 100 has changed by a predetermined value or more, the CMOS image sensor 100 executes correction processing corresponding to the temperature change at the output timing of the vertical synchronization signal Vsync. The correction at this time may be referred to as “every-V correction” and distinguished from the correction at startup. An execution time of the every-V correction may be shorter than an execution time of the correction at startup, and may be, for example, an execution time that completes the every-V correction within one frame.

Further, FIG. 9 illustrates an example in which the every-V correction is executed every predetermined number of frames and an example in which the every-V correction is executed when the temperature has changed by the predetermined value or more.

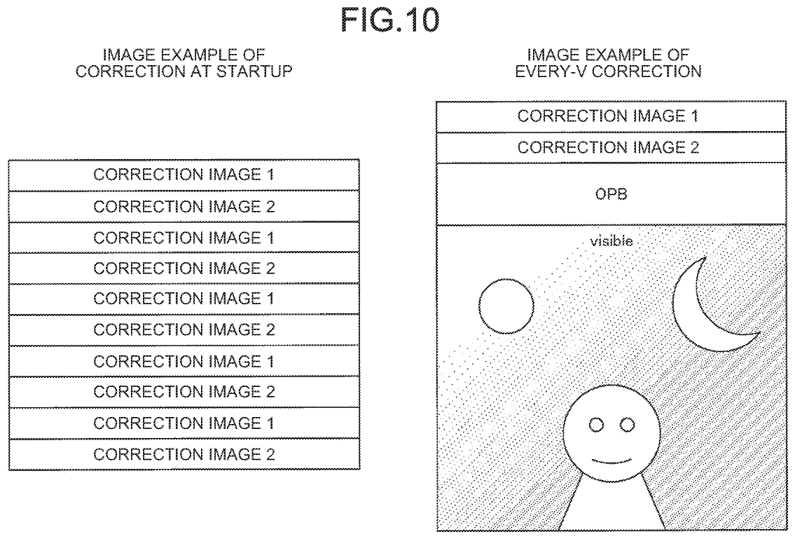

FIG. 10 is an explanatory diagram illustrating examples of the correction processing at startup and the every-V correction processing. The CMOS image sensor 100 executes correction with a set of a high voltage value (a correction image 1) and a low voltage value (a correction image 2) a plurality of times as the correction processing at startup. On the other hand, since it is assumed that the every-V correction processing is executed during imaging processing, the CMOS image sensor 100 executes the correction with the set of the high voltage value (the correction image 1) and the low voltage value (the correction image 2) only once as the every-V correction processing. Specifically, the CMOS image sensor 100 executes the correction in a blank region within one frame. The CMOS image sensor 100 can generate images with reduced noise for the subsequent frame images by executing the every-V correction processing in this manner.

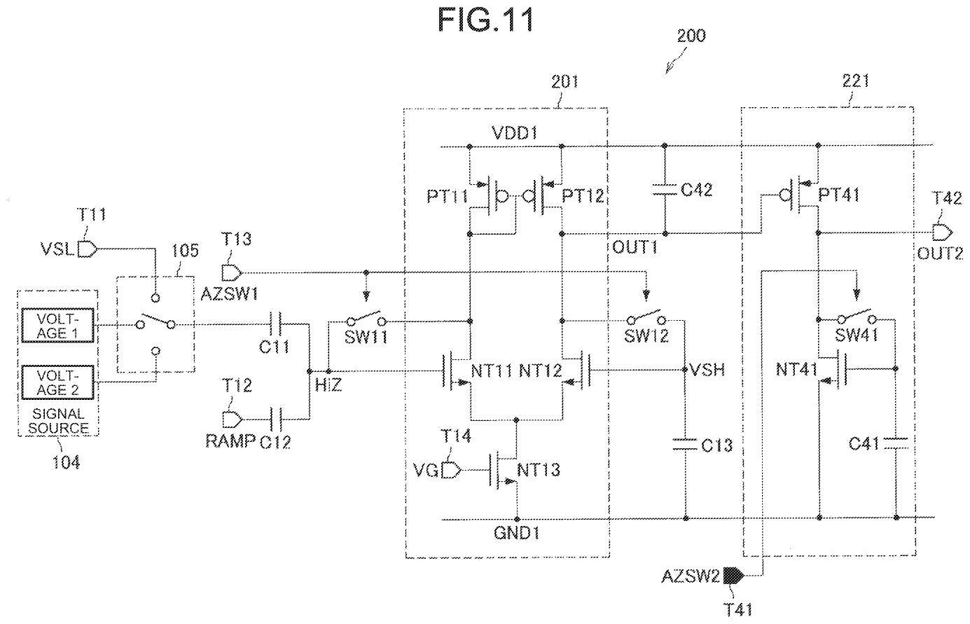

FIG. 3A illustrates an example in which the DAC capable of outputting any voltage is provided as the signal source 104. However, the present disclosure is not limited to this example. The signal source 104 may include a plurality of voltage sources each of which outputs a signal of a predetermined voltage. FIG. 11 is an explanatory diagram illustrating an example of the correction processing at startup and the every-V correction processing. FIG. 11 illustrates an example in which two voltage sources each of which outputs a signal of a predetermined voltage are provided as the signal source 104. In the correction processing, the switch unit 105 is switched to output the signal from each of the voltage sources to the comparator 200. Feeding signals from at least two voltage sources to the comparator 200 makes it possible to grasp the slope of the relationship between the light amount and the digital value as illustrated in FIG. 8. Thus, the signal processing circuit 107 can correct variations in the analog characteristic of the comparator 200 on the basis of the digital signal output from the comparator 200 in the correction processing.

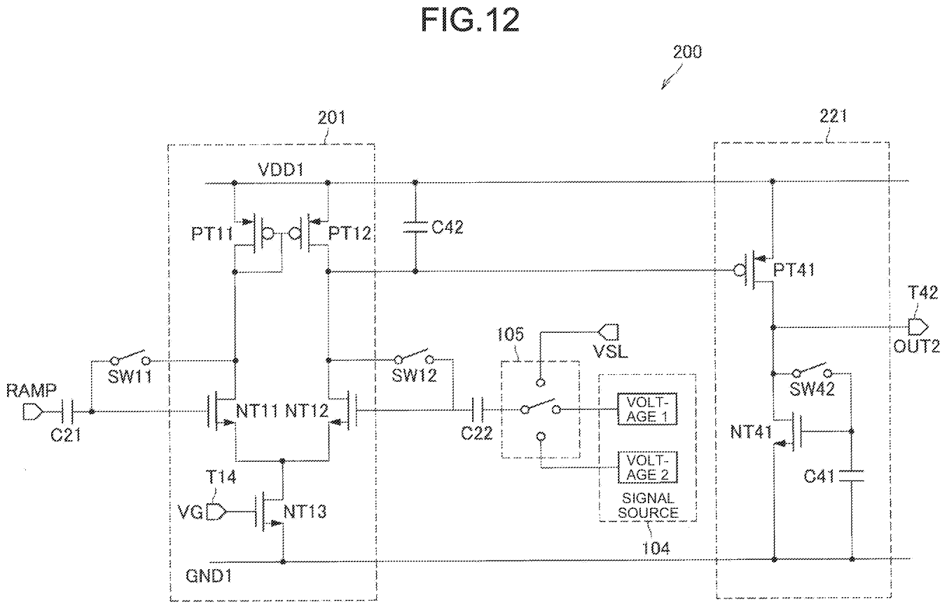

Similarly, the signal source 104 including a plurality of voltage sources each of which outputs a signal of a predetermined voltage may be connected to the comparator illustrated in FIG. 5. FIG. 12 is an explanatory diagram illustrating a configuration example of the comparator. FIG. 12 illustrates an example in which two voltage sources each of which outputs a signal of a predetermined voltage are provided as the signal source 104.

The CMOS image sensor 100 of the present embodiment may use a successive approximation register (SAR) ADC as the ADC included in the column readout circuit 103. Also in the case where the SAR ADC is used in the column readout circuit 103, the CMOS image sensor 100 of the present embodiment can correct variations in the analog characteristic of the comparator.

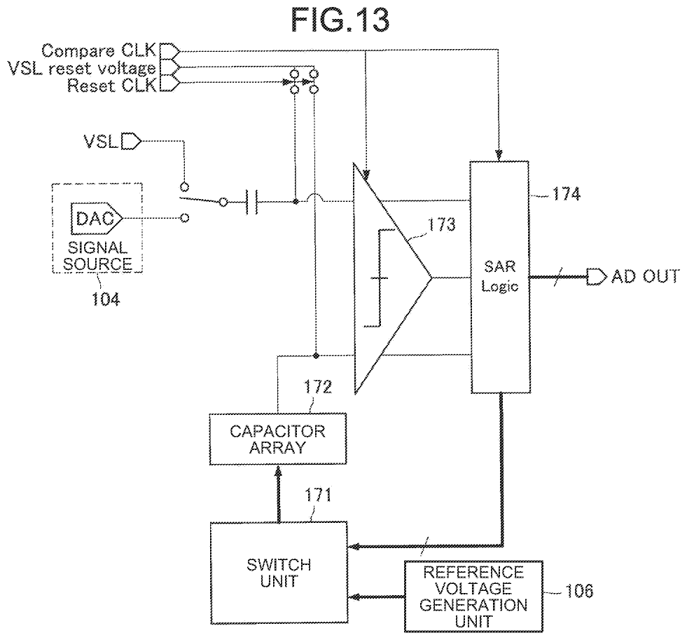

FIG. 13 is an explanatory diagram illustrating a configuration example of the SAR ADC included in the column readout circuit 103. FIG. 13 illustrates an example in which the DAC capable of outputting any voltage is provided as the signal source 104. Further, the SAR ADC is used as the ADC illustrated in FIG. 13. The ADC illustrated in FIG. 13 includes a switch unit 171, a capacitor array 172, a comparator 173, and an SAR logic circuit 174.

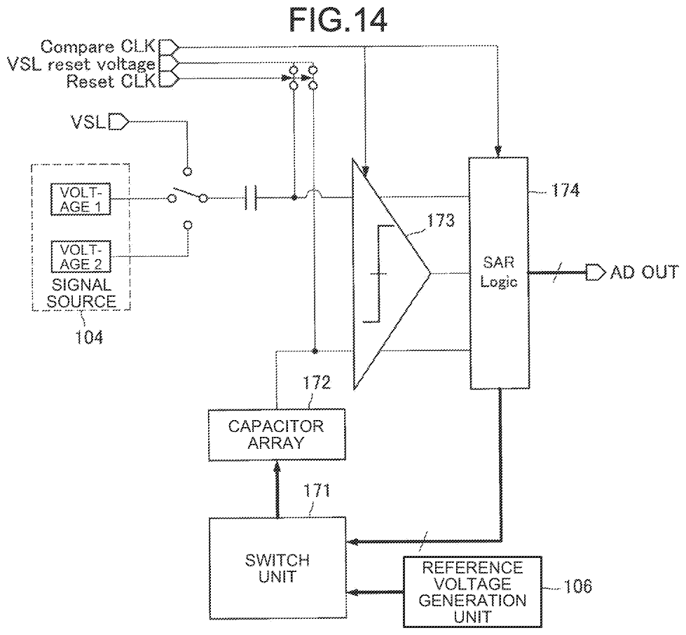

FIG. 14 is an explanatory diagram illustrating a configuration example of the SAR ADC included in the column readout circuit 103. FIG. 14 illustrates an example in which two voltage sources each of which outputs a signal of a predetermined voltage are provided as the signal source 104. Further, the SAR ADC is used as the ADC illustrated in FIG. 14, and the configuration thereof is similar to that illustrated in FIG. 13. It is needless to say that the configuration of the SAR ADC included in the column readout circuit 103 is not limited to the configurations illustrated in FIGS. 13 and 14.

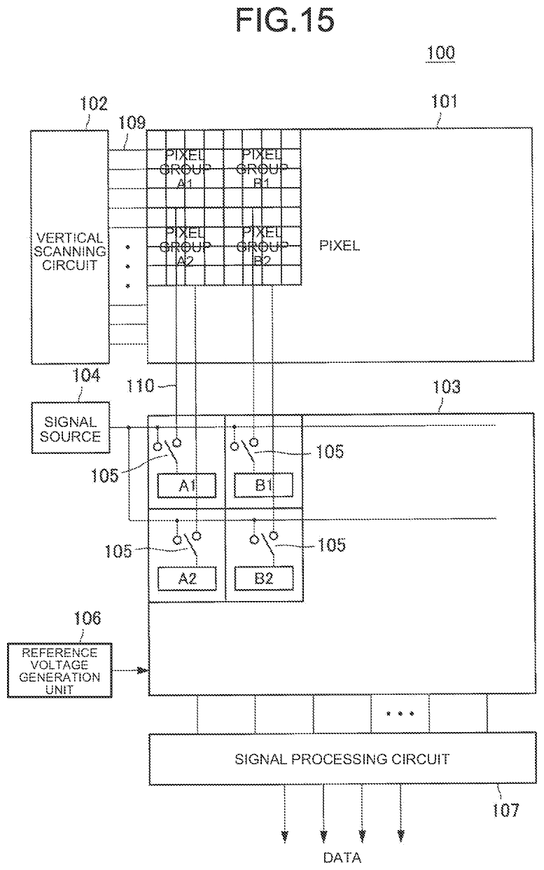

The CMOS image sensor 100 according to the present embodiment may have a configuration that reads out data photoelectrically converted by the pixel unit 101 from the pixel unit 101 not in units of columns, but in units of areas. FIG. 15 is an explanatory diagram illustrating a configuration example of the CMOS image sensor 100 according to the embodiment of the present disclosure. FIG. 15 illustrates the configuration example of the CMOS image sensor 100 having a configuration provided with a readout circuit 103 which reads out data in units of groups, each of the groups including a plurality of adjacent pixels in the pixel unit 101. In the configuration illustrated in FIG. 15, signals from a pixel group including a plurality of pixels are output to the readout circuit 103 from the pixel unit 101, and the readout circuit 103 reads out the signals from the pixel unit 101 or signals from the signal source 104 in units of pixel groups and outputs the readout signals to the signal processing circuit 107. As an example, FIG. 15 illustrates the readout circuit 103 including a readout circuit A1 which reads out signals from a pixel group A1, a readout circuit A2 which reads out signals from a pixel group A2, a readout circuit B1 which reads out signals from a pixel group B1, and a readout circuit B2 which reads out signals from a pixel group B2. Also such a configuration enables either the output from the pixel unit 101 or the output from the signal source 104 to be fed to the column readout circuit 103 by switching the switch unit 105.

### 2. Configuration Example of Stacked Solid-State Imaging Apparatus

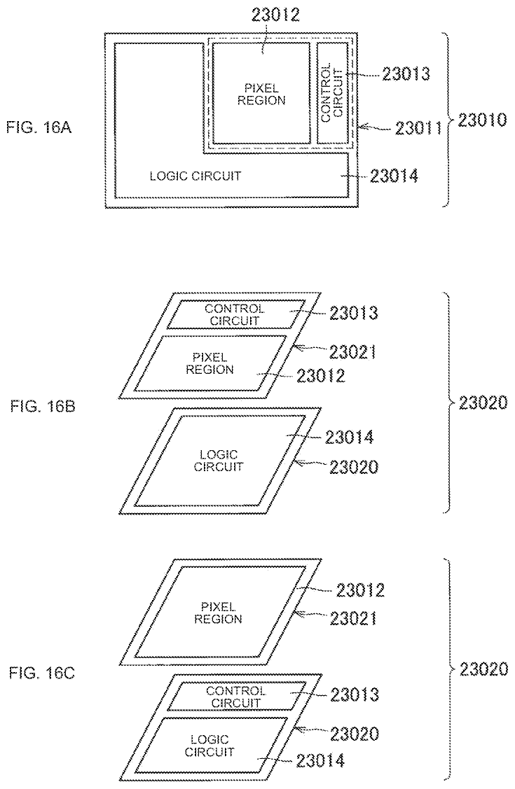

FIG. 16 is a diagram illustrating an overview of a configuration example of a stacked solid-state imaging apparatus to which the technique according to the present disclosure is applicable.

A of FIG. 16 illustrates a schematic configuration example of a non-stacked solid-state imaging apparatus. As illustrated in A of FIG. 16, a solid-state imaging apparatus 23010 includes one die (semiconductor substrate) 23011. A pixel region 23012 in which pixels are arranged in an array form, a control circuit 23013 which drives the pixels and performs other various control operations, and a logic circuit 23014 for performing signal processing are mounted on the die 23011.

B and C of FIG. 16 illustrate schematic configuration examples of a stacked solid-state imaging apparatus. As illustrated in B and C of FIG. 16, a solid-state imaging apparatus 23020 includes two dies: a sensor die 23021; and a logic die 23024 which are stacked together and electrically connected to each other to constitute one semiconductor chip.

In B of FIG. 16, the pixel region 23012 and the control circuit 23013 are mounted on the sensor die 23021, and the logic circuit 23014 including a signal processing circuit which performs signal processing is mounted on the logic die 23024.

In C of FIG. 16, the pixel region 23012 is mounted on the sensor die 23021, and the control circuit 23013 and the logic circuit 23014 are mounted on the logic die 23024.

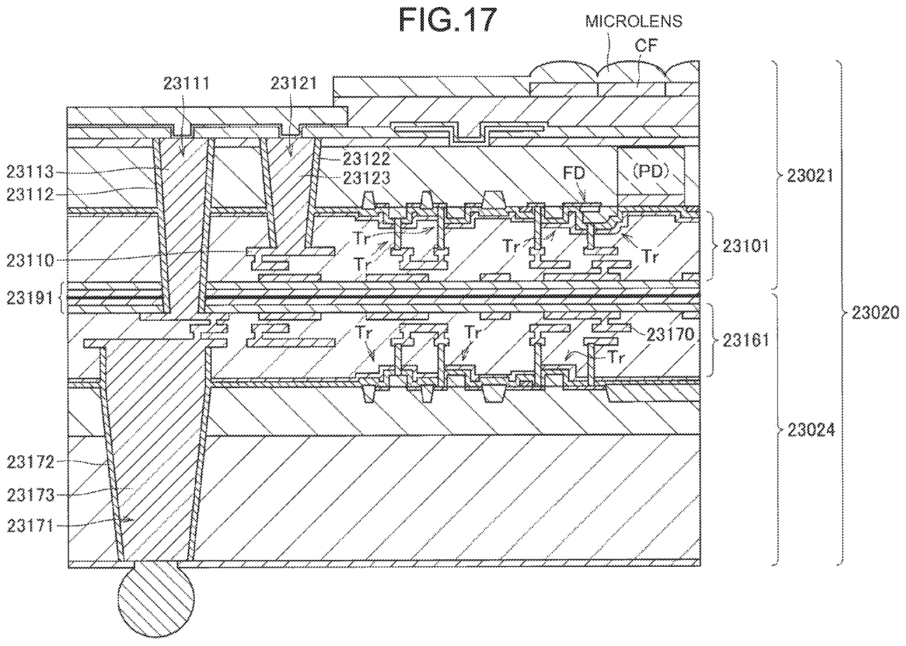

FIG. 17 is a sectional view illustrating a first configuration example of the stacked solid-state imaging apparatus 23020.

A photodiode (PD) which constitutes a pixel which serves as the pixel region 23012, a floating diffusion (FD), a Tr (MOS FET), and a Tr which serves as the control circuit 23013 are formed on the sensor die 23021. Further, a wiring layer 23101 which includes a plurality of layers (in this example, three layers of wiring 23110) is formed on the sensor die 23021. Note that the control circuit 23013 (Tr) may be formed not on the sensor die 23021, but on the logic die 23024.

A Tr which constitutes the logic circuit 23014 is formed on the logic die 23024. Further, a wiring layer 23161 which includes a plurality of layers (in this example, three layers of wiring 23170) is formed on the logic die 23024. Further, a connection hole 23171 which includes an insulating film 23172 formed on the inner wall surface thereof is formed on the logic die 23024. A connection conductor 23173 which is connected to the wiring 23170 and the like is embedded inside the connection hole 23171.

The sensor die 23021 and the logic die 23024 are bonded together with their wiring layers 23101 and 23161 facing each other to constitute the stacked solid-state imaging apparatus 23020 with the sensor die 23021 and the logic die 23024 stacked together. A film 23191 such as a protection film is formed on the bonded surfaces of the sensor die 23021 and the logic die 23024.

The sensor die 23021 includes a connection hole 23111 which penetrates the sensor die 23021 from the back face side (the side from which light enters the PD, the upper side) of the sensor die 23021 and reaches the uppermost layer of the wiring 23170 of the logic die 23024. Further, the sensor die 23021 includes a connection hole 23121 which is formed near the connection hole 23111 from the back face side of the sensor die 23021 up to the first layer of the wiring 23110. An insulating film 23112 is formed on the inner wall surface of the connection hole 23111, and an insulating film 23122 is formed on the inner wall surface of the connection hole 23121. Further, connection conductors 23113 and 23123 are embedded inside the connection holes 23111 and 23121, respectively. The connection conductor 23113 and the connection conductor 23123 are electrically connected to each other on the back face side of the sensor dies 23021. Accordingly, the sensor die 23021 and the logic die 23024 are electrically connected to each other through the wiring layer 23101, the connection hole 23121, the connection hole 23111, and the wiring layer 23161.

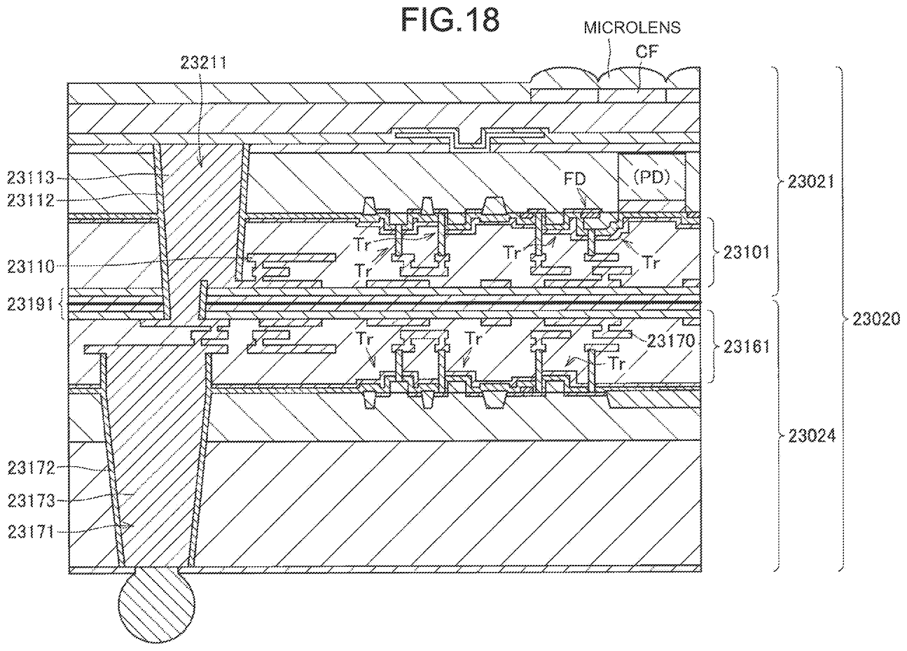

FIG. 18 is a sectional view illustrating a second configuration example of the stacked solid-state imaging apparatus 23020.

In the second configuration example of the solid-state imaging apparatus 23020, the sensor die 23021 (the wiring layer 23101 [the wiring 23110]) and the logic die 23024 (the wiring layer 23161 [the wiring 23170]) are electrically connected to each other through one connection hole 23211 which is formed on the sensor die 23021.

That is, in FIG. 18, the connection hole 23211 penetrates the sensor die 23021 from the back face side of the sensor die 23021, and reaches the uppermost layer of the wiring 23170 of the logic die 23024 and the uppermost layer of the wiring 23110 of the sensor die 23021. An insulating film 23212 is formed on the inner wall surface of the connection hole 23211, and a connection conductor 23213 is embedded inside the connection hole 23211. In FIG. 17 described above, the sensor die 23021 and the logic die 23024 are electrically connected to each other through the two connection holes 23111 and 23121. On the other hand, in FIG. 18, the sensor die 23021 and the logic die 23024 are electrically connected to each other through the single connection hole 23211.

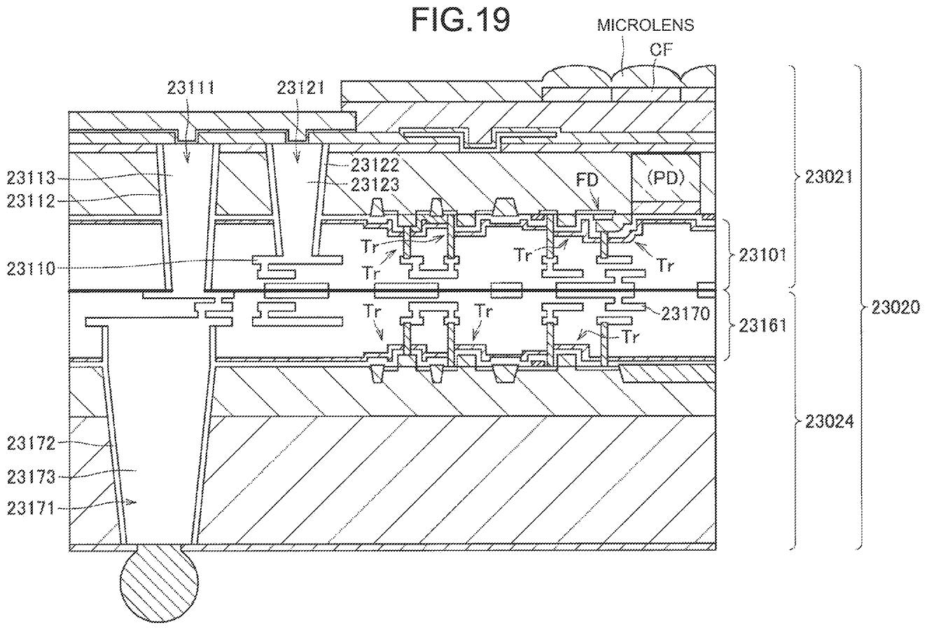

FIG. 19 is a sectional view illustrating a third configuration example of the stacked solid-state imaging apparatus 23020.

In the solid-state imaging apparatus 23020 of FIG. 19, the film 23191 such as a protection film is not formed on the bonded surfaces of the sensor die 23021 and the logic die 23024, which differs from the case of FIG. 17 where the film 23191 such as a protection film is formed on the bonded surfaces of the sensor die 23021 and the logic die 23024.

The solid-state imaging apparatus 23020 of FIG. 19 is configured in such a manner that the sensor die 23021 and the logic die 23024 are stacked together so that the wiring 23110 and the wiring 23170 are brought into direct contact with each other, and heat is applied while applying a predetermined load thereto to directly join the wiring 23110 and the wiring 23170.

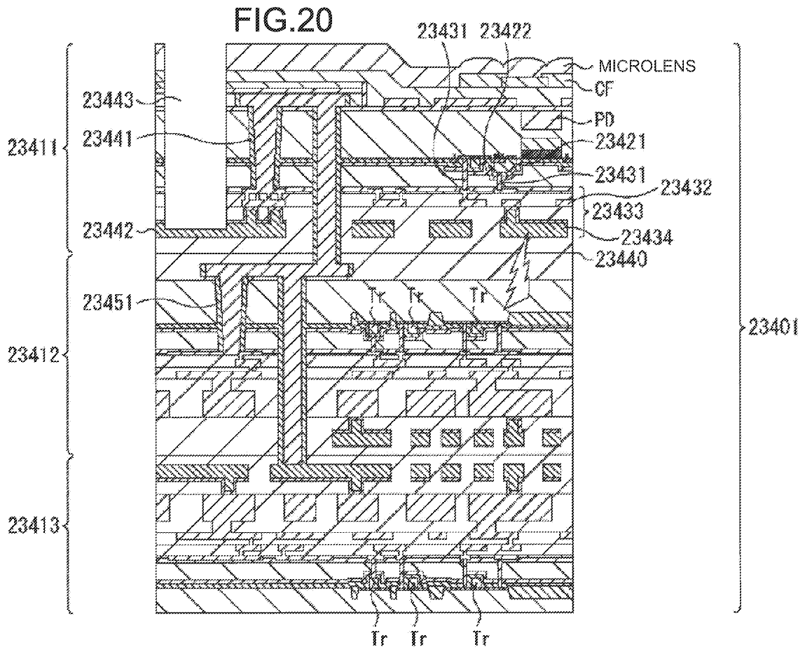

FIG. 20 is a sectional view illustrating another configuration example of the stacked solid-state imaging apparatus to which the technique according to the present disclosure is applicable.

In FIG. 20, a solid-state imaging apparatus 23401 has a three-layer stacked structure in which three dies: a sensor die 23411; a logic die 23412; and a memory die 23413 are stacked together.

The memory die 23413 includes, for example, a memory circuit which stores data temporarily required in signal processing performed in the logic die 23412.

Although the logic die 23412 and the memory die 23413 are stacked in this order under the sensor die 23411 in FIG. 20, the logic die 23412 and the memory die 23413 may be stacked in the reverse order, that is, the memory die 23413 and the logic die 23412 may be stacked in this order under the sensor die 23411.

Note that, in FIG. 20, a PD which serves as a photoelectric conversion unit of the pixel and source/drain regions of a pixel Tr are formed on the sensor die 23411.

A gate electrode is formed around the PD with a gate insulating film interposed therebetween. The gate electrode and the paired source/drain regions form a pixel Tr 23421 and a pixel Tr 23422.

The pixel Tr 23421 which is adjacent to the PD is a transfer Tr, and one of the paired source/drain regions of the pixel Tr 23421 is an FD.

Further, an interlayer insulating film is formed on the sensor die 23411, and connection holes are formed on the interlayer insulating film. Connection conductors 23431 which are connected to the pixel Tr 23421 and the pixel Tr 23422 are formed in the connection holes.

Further, a wiring layer 23433 which includes a plurality of layers of wiring 23432 which are connected to each of the connection conductors 23431 are formed on the sensor die 23411.

Further, an aluminum pad 23434 which serves as an electrode for external connection is formed on the lowermost layer of the wiring layer 23433 of the sensor die 23411. That is, in the sensor die 23411, the aluminum pad 23434 is formed at a position closer to a bonded surface 23440 bonded to the logic die 23412 than the wiring 23432 is. The aluminum pad 23434 is used as one end of a wire for input and output of signals from and to the outside.

Further, the sensor die 23411 includes a contact 23441 which is used for electrical connection with the logic die 23412. The contact 23441 is connected to a contact 23451 of the logic die 23412, and also connected to an aluminum pad 23442 of the sensor die 23411.

Further, the sensor die 23411 includes a pad hole 23443 which is formed from the back face side (upper side) of the sensor die 23411 up to the aluminum pad 23442.

The technique according to the present disclosure is applicable to the solid-state imaging apparatus as described above.

For example, the CMOS image sensor 100 according to the embodiment of the present disclosure may be produced as a stacked solid-state imaging apparatus as illustrated in B and C of FIG. 16. In this case, for example, the sensor die 23021 may be provided with the pixel unit 101, and the logic die 23024 may be provided with the vertical scanning circuit 102, the column readout circuit 103, the signal source 104, the switch unit 105, the reference voltage generation unit 106, the signal processing circuit 107, and the event control unit 108.

The technique according to the present disclosure may be applicable to an imaging apparatus included in, for example, a digital camera, a digital still camera, a mobile phone, a tablet terminal, or a personal computer. Further, the technique according to the present disclosure may be implemented as an apparatus mounted on any kind of mobile body such as a motor vehicle, an electric vehicle, a hybrid electric vehicle, a motorcycle, a bicycle, a personal mobility, an airplane, a drone, a ship, or a robot. The technique according to the present disclosure applied to the apparatus as described above makes it possible to reduce the power consumption of the imaging apparatus and generate an image with reduced noise caused by the analog characteristic of the column readout circuit.

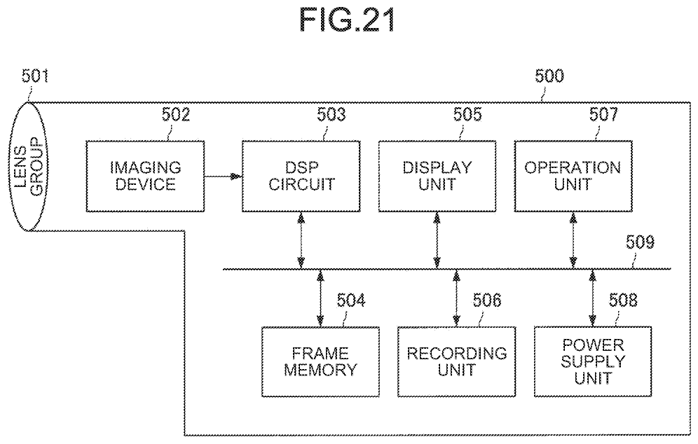

FIG. 21 is an explanatory diagram illustrating a configuration example of an electronic apparatus 500 to which the CMOS image sensor 100 according to the embodiment of the present disclosure is applied.

The electronic apparatus 500 is, for example, an imaging apparatus such as a digital still camera or a video camera or a portable terminal apparatus such as a smartphone or a tablet terminal.

In FIG. 21, the electronic apparatus 500 includes a lens 501, an imaging device 502, a DSP circuit 503, a frame memory 504, a display unit 505, a recording unit 506, an operation unit 507, and a power supply unit 508. Further, in the electronic apparatus 500, the DSP circuit 503, the frame memory 504, the display unit 505, the recording unit 506, the operation unit 507, and the power supply unit 508 are connected to each other through a bus line 509.

The CMOS image sensor 100 of FIG. 1 can be applied to the imaging device 502.

The DSP circuit 503 is a signal processing circuit that processes a signal fed from the imaging device 502. The DSP circuit 503 outputs image data obtained by processing the signal from the imaging device 502. The frame memory 504 temporarily holds the image data processed by the DSP circuit 503 in units of frames.

The display unit 505 includes, for example, a panel display such as a liquid crystal panel or an organic electro luminescence (EL) panel, and displays a moving image or a still image captured by the imaging device 502. The recording unit 506 records image data of the moving image or the still image captured by the imaging device 502 in a recording medium such as a semiconductor memory or a hard disk.

The operation unit 507 outputs an operation command for various functions included in the electronic apparatus 500 in accordance with an operation by a user. The power supply unit 508 appropriately supplies various power to be operation power of the DSP circuit 503, the frame memory 504, the display unit 505, the recording unit 506, and the operation unit 507 to these supply targets.

### 3. Summary

As described above, the embodiment of the present disclosure can provide the CMOS image sensor 100 capable of generating an image with reduced noise caused by the analog characteristic of the column readout circuit.

The preferred embodiment of the present disclosure has been described in detail above with reference to the accompanying drawings. However, the technical scope of the present disclosure is not limited to the above examples. It is obvious that those skilled in the art of the present disclosure can conceive various modifications or corrections within the range of the technical idea described in claims, and it should be understood that these modifications and corrections also belong to the technical scope of the present disclosure as a matter of course.

Further, the effects described in the present specification are not limited effects, but solely explanatory or illustrative effects. In other words, the technique according to the present disclosure can achieve other effects that are obvious to those skilled in the art from the description of the specification, in addition to or instead of the above effects.

Note that the configurations as described below also belong to the technical scope of the present disclosure.

(1) An imaging device comprising:

a pixel array including a plurality of pixels each configured to output a pixel signal by photoelectric conversion;

a signal output unit configured to output a predetermined signal;

a switch unit configured to output either an output from the signal output unit or an output based on the pixel signal in a switching manner; and
an AD conversion processing unit configured to execute AD conversion using an output from the switch unit.
   (2) The imaging device according to (1), further comprising a control unit configured to perform control for switching the switch unit so as to output the output from the signal output unit to the AD conversion processing unit when a predetermined condition is satisfied.
   3) The imaging device according to (2), wherein the control unit switches the switch unit so as to output the output from the signal output unit to the AD conversion processing unit at a predetermined period.
   (4) The imaging device according to (2) or (3), wherein the control unit switches the switch unit so as to output the output from the signal output unit to the AD conversion processing unit in response to detection of a predetermined temperature change.
   (5) The imaging device according to (2) or (3), wherein the control unit switches the switch unit so as to output the output from the signal output unit to the AD conversion processing unit in response to detection of a predetermined voltage change.
   (6) The imaging device according to any one of (1) to (5), wherein the signal output unit outputs a signal of any voltage value.
   (7) The imaging device according to any one of (1) to (5), wherein the signal output unit outputs at least signals of two voltage values in a switching manner.
   (8) The imaging device according to any one of (1) to (7), wherein the AD conversion processing unit converts the pixel signal to a digital signal on the basis of a result of comparison between a first voltage corresponding to a signal obtained by adding the pixel signal and a reference signal linearly changing in a direction opposite to the pixel signal and a second voltage serving as a reference.
   (9) The imaging device according to (8), wherein the AD conversion processing unit includes a comparator configured to perform the comparison between the first voltage and the second voltage and output an output signal indicating the comparison result.
   (10) The imaging device according to (9), further comprising a signal processing circuit configured to execute signal processing on an output from the AD conversion processing unit.
   (11) The imaging device according to (10), wherein the signal processing circuit executes signal processing for calculating a correction value for making a relationship between a light amount and a digital value uniform between outputs from a plurality of the AD conversion processing units in a state where the switch unit outputs the output from the signal output unit to the AD conversion processing unit.
   (12) The imaging device according to (11), wherein the signal processing circuit performs correction processing on the output from the AD conversion processing unit using the correction value in a state where the switch unit outputs an output from the pixel array to the AD conversion processing unit.
   (13) The imaging device according to any one of (1) to (12), wherein the AD conversion processing unit includes at least one comparator, and the comparator includes a first differential transistor and a second differential transistor.
   (14) The imaging device according to (13), wherein a reference signal is input to the first differential transistor, and the output from the signal output unit or the output based on the pixel signal is selectively input to the second differential transistor through the switch unit.
   (15) The imaging device according to (13) or (14), wherein the first differential transistor is connected to a reference voltage, and the second differential transistor is connected to a first capacitor and a second capacitor.
   (16) The imaging device according to (15), wherein a reference signal is input to the first capacitor, and the output based on the pixel signal or the output from the signal output unit is selectively input to the second capacitor through a switch.
   (17) The imaging device according to (16), wherein the reference voltage is a ground voltage.
   (18) An imaging device control method for controlling an imaging device, the imaging device including:

a pixel array including a plurality of pixels each configured to output a pixel signal by photoelectric conversion;

a signal output unit configured to output a predetermined signal;

a switch unit configured to output either an output from the signal output unit or an output based on the pixel signal in a switching manner; and

an AD conversion processing unit configured to execute AD conversion using an output from the switch unit, the method comprising:

performing control for switching the switch unit so as to output the output from the signal output unit to the AD conversion processing unit when a predetermined condition is satisfied.

(19) An electronic apparatus comprising:

an imaging device; and

a processing unit configured to process a signal output from the imaging device, wherein

the imaging device including:

a pixel array including a plurality of pixels each configured to output a pixel signal by photoelectric conversion;

a signal output unit configured to output a predetermined signal;

a switch unit configured to output either an output from the signal output unit or an output based on the pixel signal in a switching manner; and

an AD conversion processing unit configured to execute AD conversion using an output from the switch unit.

### REFERENCE SIGNS LIST

100 CMOS image sensor

109 pixel driving line

110 vertical signal line

121 comparator

122 counter

123 latch

150 pixel

151 photodiode

152 transfer transistor

154 amplification transistor

155 selection transistor

156 reset transistor

157 constant current source

171 switch unit

172 capacitor array

173 comparator

174 SAR logic circuit

200 comparator

201 differential amplifier

1. An imaging device comprising:
a pixel array including a plurality of pixels each configured to output a pixel signal by photoelectric conversion;
a signal output unit configured to output a predetermined signal;
a switch unit configured to output either an output from the signal output unit or an output based on the pixel signal in a switching manner; and
an AD conversion processing unit configured to execute AD conversion using an output from the switch unit.

2. The imaging device according to claim 1, further comprising a control unit configured to perform control for switching the switch unit so as to output the output from the signal output unit to the AD conversion processing unit when a predetermined condition is satisfied.

3. The imaging device according to claim 2, wherein the control unit switches the switch unit so as to output the output from the signal output unit to the AD conversion processing unit at a predetermined period.

4. The imaging device according to claim 2, wherein the control unit switches the switch unit so as to output the output from the signal output unit to the AD conversion processing unit in response to detection of a predetermined temperature change.

5. The imaging device according to claim 2, wherein the control unit switches the switch unit so as to output the output from the signal output unit to the AD conversion processing unit in response to detection of a predetermined voltage change.

6. The imaging device according to claim 1, wherein the signal output unit outputs a signal of any voltage value.

7. The imaging device according to claim 1, wherein the signal output unit outputs at least signals of two voltage values in a switching manner.

8. The imaging device according to claim 1, wherein the AD conversion processing unit converts the pixel signal to a digital signal on the basis of a result of comparison between a first voltage corresponding to a signal obtained by adding the pixel signal and a reference signal linearly changing in a direction opposite to the pixel signal and a second voltage serving as a reference.

9. The imaging device according to claim 8, wherein the AD conversion processing unit includes a comparator configured to perform the comparison between the first voltage and the second voltage and output an output signal indicating the comparison result.

10. The imaging device according to claim 9, further comprising a signal processing circuit configured to execute signal processing on an output from the AD conversion processing unit.

11. The imaging device according to claim 10, wherein the signal processing circuit executes signal processing for calculating a correction value for making a relationship between a light amount and a digital value uniform between outputs from a plurality of the AD conversion processing units in a state where the switch unit outputs the output from the signal output unit to the AD conversion processing unit.

12. The imaging device according to claim 11, wherein the signal processing circuit performs correction processing on the output from the AD conversion processing unit using the correction value in a state where the switch unit outputs an output from the pixel array to the AD conversion processing unit.

13. The imaging device according to claim 1, wherein the AD conversion processing unit includes at least one comparator, and the comparator includes a first differential transistor and a second differential transistor.

14. The imaging device according to claim 13, wherein a reference signal is input to the first differential transistor, and the output from the signal output unit or the output based on the pixel signal is selectively input to the second differential transistor through the switch unit.

15. The imaging device according to claim 13, wherein the first differential transistor is connected to a reference voltage, and the second differential transistor is connected to a first capacitor and a second capacitor.

16. The imaging device according to claim 15, wherein a reference signal is input to the first capacitor, and the output based on the pixel signal or the output from the signal output unit is selectively input to the second capacitor through a switch.

17. The imaging device according to claim 16, wherein the reference voltage is a ground voltage.

18. An imaging device control method for controlling an imaging device, the imaging device including:
a pixel array including a plurality of pixels each configured to output a pixel signal by photoelectric conversion;
a signal output unit configured to output a predetermined signal;
a switch unit configured to output either an output from the signal output unit or an output based on the pixel signal in a switching manner; and
an AD conversion processing unit configured to execute AD conversion using an output from the switch unit, the method comprising:
performing control for switching the switch unit so as to output the output from the signal output unit to the AD conversion processing unit when a predetermined condition is satisfied.

19. An electronic apparatus comprising:
an imaging device; and
a processing unit configured to process a signal output from the imaging device, wherein
the imaging device including:
a pixel array including a plurality of pixels each configured to output a pixel signal by photoelectric conversion;
a signal output unit configured to output a predetermined signal;
a switch unit configured to output either an output from the signal output unit or an output based on the pixel signal in a switching manner; and
an AD conversion processing unit configured to execute AD conversion using an output from the switch unit.
